(19) United States
(12) Patent Application Publication
(10) Pub. No.: US 2004/0056701 A1
(43) Pub. Date: Mar. 25, 2004

(54) Interface circuitry for display chip

(76) Inventor: Sterling Smith, Hsinchu (TW)

Correspondence Address: Michael D. Bednarek, Shaw Pittman LLP, 1650 Tysons Boulevard, McLean, VA, 22102, US

(21) Appl. No.: 10/663,755

(22) Filed: Sep. 17, 2003

Related U.S. Application Data
(60) Provisional application No. 60/412,791, filed on Sep. 24, 2002.

(51) Int. Cl. H03L 5/00

(52) U.S. Cl. 327/333

(57) ABSTRACT

An interface circuitry of a display chip is disclosed. According to the present invention, the interface circuitry comprises an input node, a filter and a clamping circuit. The input node is used for receiving an analog image signal. The filter is utilized for processing the analog image signal and providing a processed image signal at an internal node. The clamping circuit is connected between the internal node and a reference level. The clamping circuit is used to clamp the processed image signal by the reference level during a clamping interval.

### CROSS-REFERENCE TO RELATED APPLICATION

This application claims the priority benefits of U.S. provisional application titled “APPARATUS AND METHOD FOR MASKING INTERFERENCE NOISE CONTAINED IN SIGNAL SOURCE” filed on Sep. 24, 2002, serial No. 60/412,791. All disclosure of this application is incorporated herein by reference.

### BACKGROUND OF THE INVENTION

1. Field of the Invention

The present invention relates to interface circuitry for display controller. More particularly, the present invention relates to an interface circuitry having a clamping circuit to be integrated with a low-pass filter.

2. Description of the Prior Art

Currently, most personal computers utilize graphic cards that convert digital signals into RGB analog signals for displaying graphics or video on the monitor connected thereto. To be compatible with the current PC systems, a flat-panel display should be provided with a display control board having ADC converter or display control ICs to process the RGB analog signals. The RGB analog signals are typically brought into the control board of the flat-panel display via a 15-pin D-type connector.

Referring to FIG. 1, a circuit diagram of a conventional interface circuitry for an ADC chip or a display controller chip is schematically illustrated. In FIG. 1, reference numeral 1 designates an ADC chip or a display controller chip in which an input node 10, a clamping circuit 12, a low pass filter 14 and an ADC unit 16 are provided. An analog image signal Vin is received, and typically resistively terminated through a resistor Rb and capacitively coupled to the input node 10 of the chip 1 through a capacitor Cb. The resistor Rb and the capacitor Cb are mounted on the display control board, and thus external to the chip 1. It is noted that the capacitor Cb forms part of the DC restoration circuits. The clamping circuit 12 and the low pass filter 14 constitute an interface circuitry such that the ADC 16 can properly digitize the analog image signal Vin.

The clamping circuit 12 is connected between the input node 10 and a reference level REF. The low pass filter 14 is connected between the input node 10 and an input of the ADC unit 16. The image signal Vin is coupled to the input node 10 through the capacitor Cb. The clamping circuit 12 is used to adjust the reference level of the coupled image signal to form an adjusted image signal Vc which fits in with the corresponding internal reference level determined by ADC unit 16. The low pass filter 14 is used to remove high-frequency noise from the adjusted image signal 13, typically based upon anti-aliasing requirements, so as to generate a filtered image signal Vf. In general, the higher the display resolution is selected, the greater the filter bandwidth is required. The ADC unit 16 is connected to the low-pass filter 14 for converting the filtered image signal Vf into a digital image signal.

The clamping circuit 12 is employed to generate an adjusted image signal Vc fitting in with the corresponding internal reference level determined by ADC unit 16. The key to clamping is to identify a period of time (“clamping interval”) that the input signals are known to be producing a known reference level, such as a black level or a middle level. The clamping circuit 12 is enabled during that period to adjust the reference level to the desired voltage. In other words, the clamping circuit 12 performs the clamping during the clamping interval so as to adjust the reference level of the input signals.

In the conventional interface circuitry of FIG. 1, the input noise level and the required input bandwidth vary significantly from different input modes and video source. In addition, aliasing from the input noise can affect detrimentally both the clamping level and the ADC output.

### SUMMARY OF THE INVENTION

It is therefore an objective of the present invention to provide an interface circuitry configured with a clamping circuit integrated with a low-pass filter so as to solve the above-mentioned problem.

For attaining the above objective, the present invention provides an interface circuitry of a display chip. The interface circuitry comprising: an input node for receiving an analog image signal; a filter for processing the analog image signal and providing a processed image signal at an internal node; and a clamping circuit connected between the internal node and a reference level; wherein the clamping circuit is used to clamp the processed image signal by the reference level during a clamping interval.

Moreover, the present invention provides an interface circuitry of a display chip, comprising: an input node for receiving an analog image signal; a filter for processing the analog image signal and providing a processed image signal at an internal node; an ADC unit for converting the processed image signal into a digital image signal; and a clamping circuit connected between the internal node and a reference level; wherein the clamping circuit is used to clamp the processed image signal by the reference level during a clamping interval.

### BRIEF DESCRIPTION OF THE DRAWINGS

The accompanying drawings, which are incorporated in and form part of the specification in which like numerals designate like parts, illustrate preferred embodiments of the present invention and together with the description, serve to explain the principles of the invention. In the drawings:

FIG. 1 is a circuit diagram of a conventional interface circuitry for an ADC chip or a display controller chip;

FIG. 2 is a circuit diagram of an interface circuitry for an ADC chip or a display controller chip in accordance with one preferred embodiment of the present invention; and

FIG. 3 is a circuit diagram of an interface circuitry for an ADC chip or a display controller chip in accordance with another preferred embodiment of the present invention.

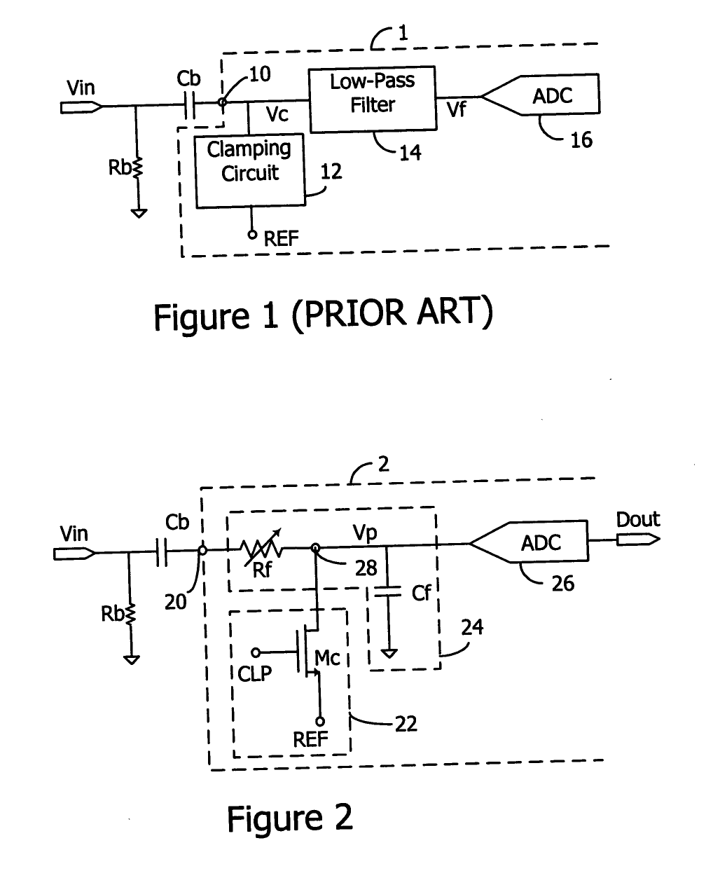

### DETAILED DESCRIPTION OF THE PREFERRED EMBODIMENTS

In the following detailed description of the preferred embodiments, reference is made to the accompanying drawings that form a part hereof, and in which is shown by way of illustration specific preferred embodiments in which the invention may be practiced. The preferred embodiments are described in sufficient detail to enable these skilled in the art to practice the invention, and it is to be understood that other embodiments may be utilized and that logical, changes may be made without departing from the spirit and scope of the present invention. The following detailed description is, therefore, not to be taken in a limiting sense, and the scope of the present invention is defined only by the appended claims.

Referring to FIG. 2, a circuit diagram of an interface circuitry for an ADC chip or a display controller chip in accordance with one preferred embodiment of the present invention is schematically illustrated. In FIG. 2, reference numeral 2 designates an ADC chip or a display controller chip in which an input node 20, a clamping circuit 22, a low pass filter 24 and an ADC unit 26 are provided. An analog image signal Vin is received, and typically resistively terminated through a resistor Rb and capacitively coupled to the input node 20 of the chip 2 through a capacitor Cb. The resistor Rb and the capacitor Cb are mounted on a display control board, and thus external to the chip 2. It is noted that the capacitor Cb forms part of the DC restoration circuits. The clamping circuit 22 and the low pass filter 24 constitute an interface circuitry such that the ADC 26 can properly digitize the analog image signal Vin.

As shown in FIG. 2, the low pass filter 24 comprises a variable resistor Rf connected between the input node 20 and an internal node 28 and a capacitor Cf connected between the internal node 28 and a ground node. The variable resistor Rf is utilized to provide different resistances upon the display mode and required bandwidth as well. As an example, the resistance provided for the VGA mode of a 640×480 active resolution should be greater than that for the XGA mode of a 1024×768 active resolution. The low pass filter 24 is used to remove high-frequency noise from the image signal Vin, typically based upon anti-aliasing requirements, so as to generate a processed image signal Vp at the internal node 28.

The clamping circuit 22 comprises an NMOS transistor Mc configured with its drain connected to the internal node 28, its source connected to a reference level REF and its gate controlled by a clamping signal CLP. As shown in FIG. 2, the variable resistor Rf is connected between the external capacitor Cb and the clamping circuit 22 such that the variable resistor Rf serves as a current-limiting element in the path from the input node 20 through the clamping circuit 22 to a reference level REF (e.g., ground potential in this embodiment) during the clamping interval. In this embodiment, the NMOS transistor Mc is turned on when the clamping signal CLP is asserted during the clamping interval. Accordingly, the clamping circuit 22 performs the clamping during the clamping interval so as to adjust the reference level of the image signal Vp at the internal node 28 to fit in with the corresponding internal reference level determined by ADC unit 26. Furthermore, the ADC 26 is connected to the internal node 28 for converting the processed image signal Vp into a digital image signal Dout.

According to the present invention, the selected resistance of the variable resistor Rf limits the change in the voltage across the capacitor Cb during the clamping interval. The variable resistor Rf and the external capacitor Cb form an anti-aliasing filter during the clamping interval. Though the different display modes and required bandwidths are applied, by selecting the resistance of the variable resistor Rf, the clamping circuit 22 and the low-pass filter 24 can be controlled so as to avoid the noisy artifacts and provide a better display quality.

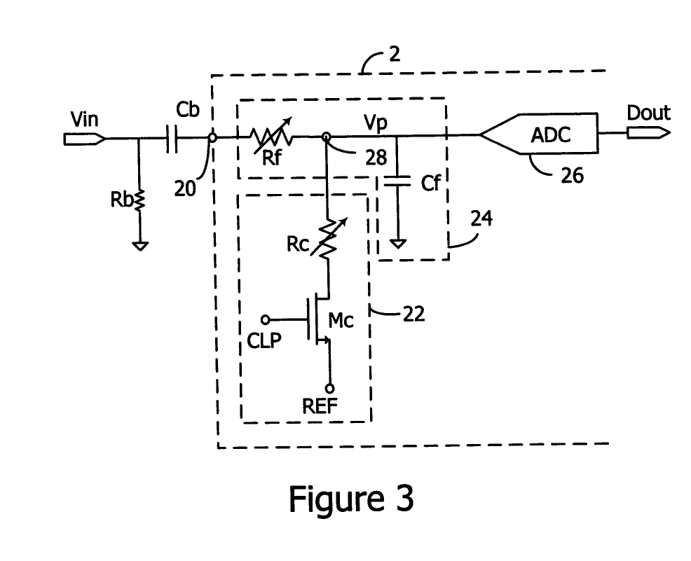

Referring to FIG. 3, a circuit diagram of an interface circuitry for an ADC chip or a display controller chip in accordance with another preferred embodiment of the present invention is schematically illustrated. In this embodiment, the clamping circuit 22 comprises a variable resistor Rc and an NMOS transistor Mc connected in series. The variable resistor Rc is connected between the internal node 28 and the drain of the NMOS transistor Mc. The variable resistor Rc, the variable resistor Rf and the external capacitor Cb form an anti-aliasing filter during the clamping interval. Thus, the bandwidth of anti-aliasing filter can be adjusted without affecting the low pass filter 24 for ADC 26.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. An interface circuitry of a display chip, said interface circuitry comprising:
an input node for receiving an analog image signal;
a filter for processing said analog image signal and providing a processed image signal at an internal node; and
a clamping circuit connected between said internal node and a reference level;
wherein said clamping circuit is used to clamp said processed image signal by said reference level during a clamping interval.

2. The interface circuitry as claimed in claim 1, wherein said filter comprises:
a variable resistor electrically connected between said input node and said internal node; and
a capacitor electrically connected between said internal node and a ground node.

3. The interface circuitry as claimed in claim 1, wherein said clamping circuit comprises a transistor connected between said internal node and said reference level.

4. The interface circuitry as claimed in claim 3, wherein said transistor is configured with a drain connected to said internal node, a source connected to said reference level and a gate controlled by a clamping signal.

5. The interface circuitry as claimed in claim 1, wherein said clamping circuit comprises:
a variable resistor connected to said internal node; and
a transistor connected between said variable resistor and said reference level.

6. The interface circuitry as claimed in claim 5, wherein said transistor is configured with a drain connected to said variable resistor, a source connected to said reference level and a gate controlled by a clamping signal.

7. An interface circuitry of a display chip, said interface circuitry comprising:
an input node for receiving an analog image signal;
a filter for processing said analog image signal and providing a processed image signal at an internal node;
an ADC unit for converting said processed image signal into a digital image signal; and
a clamping circuit connected between said internal node and a reference level;
wherein said clamping circuit is used to clamp said processed image signal by said reference level during a clamping interval.

8. The interface circuitry as claimed in claim 7, wherein said filter comprises:
a variable resistor electrically connected between said input node and said internal node; and
a capacitor electrically connected between said internal node and a ground node.

9. The interface circuitry as claimed in claim 7, wherein said clamping circuit comprises a transistor connected between said internal node and said reference level.

10. The interface circuitry as claimed in claim 9, wherein said transistor is configured with a drain connected to said internal node, a source connected to said reference level and a gate controlled by a clamping signal.

11. The interface circuitry as claimed in claim 7, wherein said clamping circuit comprises:
a variable resistor connected to said internal node; and
a transistor connected between said variable resistor and said reference level.

12. The interface circuitry as claimed in claim 11, wherein said transistor is configured with a drain connected to said variable resistor, a source connected to said reference level and a gate controlled by a clamping signal.
